(19) United States
(12) Patent Application Publication
(10) Pub. No.: US 2005/0285281 A1
(43) Pub. Date: Dec. 29, 2005

(54) Pad-limited integrated circuit

(76) Inventor: Asher Lor Simmons, Corvallis, OR (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/879,290

(22) Filed: Jun. 29, 2004

(51) Int. Cl. H01L 23/48

(52) U.S. Cl. 257/786

(57) ABSTRACT

An integrated circuit having bond pads disposed in a core logic area. According to one embodiment of the invention, an IC includes a core logic area surrounded by first set of bond pads wherein each bond pad in the first set of bond pads disposed in a bond-pad ring and operable to provide a external signal connection point. The IC further includes a second set of bond pads wherein each bond pad in the second set of bond pads disposed in core logic area and operable to provide a external signal connection point. Such an integrated circuit is able to be designed and manufactured smaller than conventional ICs because additional bond pads are disposed in the core logic area of the IC.

### BACKGROUND OF THE INVENTION

The design and manufacture of integrated circuits (ICs) continues to improve with technology such that ICs are becoming smaller and smaller in size. At the same time, the sheer number of logical functions and components that may be implemented on an IC is being realized in smaller amounts of silicon space allowing for smaller ICs and ICs with much greater functionality. Thus, the size of a typical IC has become smaller and smaller as more functionality is able to designed into a single IC. Furthermore, other physical attributes of an IC have also continued to be manufactured in smaller dimensions. More specifically, bond pads, bond wires, and IC packages have also become smaller with the advance of technology in ICs. However, the pace at which the logic and functionality has improved in an IC has been greater than the pace at which the other physical attributes (i.e., bond pads, bond wires) have improved. That is, it is now often possible to fit as much functional circuitry on the IC as is desired while only being limited in the design of the IC by the physical size of the bond pads required to interface with the functional circuitry. This has led to a problem known as “pad-limited” IC designs because the IC is limited as to how small it can be designed by the required number of bond pads.

A typical IC includes a core logic area that is reserved for the functional circuitry of the IC and several bond pads that surround the core logic area and arranged in a bond pad ring pattern. Each bond pad provides an interface to some portion of the functional circuitry in the core logic area such that an external component (i.e., power supply, ground terminal, I/O device) may pass signals between the IC and the external component. Typically, the bond-pad ring is configured to maximize the number of bond pads that may be physically present on the IC in order to provide a maximum number of signal paths to and from the IC which, in turn, allows for maximum functionality to be designed into the core logic area of the IC. As such, a typical IC has a core logic area surrounded on its four sides by rows of bond pads to form a rectangular bond-pad ring. Thus, the size of the core logic area is necessarily a function of the number of bond pads in the bond-pad ring. Therefore, when the functional circuitry required does not use all of the space in the core logic area as dictated by the number of bond pads, the size and subsequent design of the IC is pad-limited. This concept is discussed in greater detail below with respect to FIGS. 1A and 1B.

Notwithstanding its name, a bond-pad ring is typically the four sides of the IC having rows of bond pads arranged in a rectangular manner around the outside edges of a core logic area. The actual size of each bond pad in the bond-pad ring is typically a function of the size of the bond wire that attaches to the bond pad. Generally, the longer the bond wire is, the bigger the bond pad is, and consequently, bond sites (which are the physical locations where the bond wire attaches to bond pads) are also larger in order to accommodate the larger bond wire. As such, typical bond pads have a width of about 80 to 150 μm.

In the past, the pattern in which the bond pads were arranged in the bond-pad ring allowed a designer some flexibility in maximizing the number of bond pads in an IC design while minimizing the total area for the IC. Two popular bond-pad ring patterns used in conventional bond IC are inline bond pads and staggered bond pads. An example of an inline bond-pad ring is shown in FIG. 1A and is described below. An example of a staggered bond-pad ring as is shown in FIG. 1B and is also described below.

FIG. 1A is a top view of a conventional IC 100 having an inline bond-pad ring pattern. As can be seen, arrays of bond pads are situated on each rectangular side of the IC 100 and surround the core logic area 101. The arrays form the bond-pad ring 105. Each array of bond pads includes several individual bond pads 110; 14 to be exact in the IC 100 of FIG. 1A. Further, each bond pad 110 includes a bond-pad logic area 111 and a bond site 112. The bond pad logic area 111 typically includes logic (not shown) for signal processing circuitry such as buffers, voltage translators, directional control, etc. As discussed briefly above, the bond site 112 is where the actual bond wire (also not shown) attaches to the bond pad 110. The other end of the bond wire is attached to an IC package (also not shown) that provides electrical connections to a device or component for which the IC 100 is designed. Bond wires, bond sites, and IC packages are well known in the art and will not be discussed further.

In the inline bond-pad ring pattern, each of the bond sites 112 are facing the same way and are typically on the outside edge of the bond-pad ring 105; i.e., farthest from the core logic area 101. As such, bond wires attached to the bond pads 110 have the shortest length to travel to get off-chip. However, in some inline ring patterns (not shown), the bond sites 112 may be closest to the core logic area 101. Of course, the length for bond wires to traverse is greater (in order to get from off-chip over the bond pad logic area 111 to the bond site 112) such that the bond site 112 then becomes wider in order to accommodate larger bond wires.

As can be seen in FIG. 1A, there are a total of 56 bond pads 110 (14 per side) that surround the core logic area 101. These 56 bond pads interface with the core logic 102 in the core logic area 101. In this example, the core logic 102 does not use the entire space available in the core logic area 101 resulting in wasted space 103. This wasted space 103 typically goes unused to the detriment of the IC design because wasted space on an IC is wasted money when manufactured in large quantities. Since extra space is still available, a designer may choose to increase the amount of core logic 101 by adding more functionality to the IC design. However, the designer must avoid adding functionality that requires additional power or I/O because additional bond pads 110 would then be required. As such, new bond pads 110 would have to be added to the IC 100 which then increase the size of the bond-pad ring and, in turn, increase the size of the core logic area 101, resulting in the same amount, if not more, wasted space 103. Further, as the core logic is implemented in smaller and smaller amount of space, the amount of power and ground pads required for the increased functionality of more core logic has increased, thus exacerbating the problem.

FIG. 1B is a top view of a conventional IC 150 having a staggered bond-pad ring pattern. As can be seen, the arrays of bond pads are situated on each rectangular side of the IC 150 and surround the core logic area 151 to form the bond-pad ring 155. Each array of bond pads includes several individual bond pads 160; 14 to be exact in the IC 150 of FIG. 1B. Further, each bond pad 160 again includes a bond-pad logic area 161 and a bond site 162 where bond wires (not shown) may attach to respective bond sites 162 in a conventional manner.

In the staggered bond-pad ring pattern, each of the bond sites 162 face opposite direction in an alternating pattern; i.e., bond sites 162 on the 1^{st}, 3^{rd}, 5^{th}, etc are farthest from the core logic area 151 and bond sites 162 on the 2^{nd}, 4^{th}, 6^{th}, etc. are closest to the core logic area 151. Again, the length for the bond wire to traverse is greater for every other bond pad 160 such that the bond site 162 then becomes wider in order to accommodate larger bond wires.

Again, as can be seen in FIG. 1B, the actual space required for the core logic 152 is smaller than the space available in the core logic area 151. Thus, some area is, again, wasted space 153. This wasted space 153 cannot be recovered because the IC may not be manufactured smaller due to the required number of bond pads 160. A designer may choose to add additional logic functions to the overall IC design, but, it is often the case that even adding as much additional functionality to the IC that a designer can think of, the wasted space 153 still remains or the addition of more functional logic may require more bond pads.

### SUMMARY OF THE INVENTION

An embodiment of the invention is directed to an integrated circuit having bond pads disposed in a core logic area. More specifically, one embodiment of the invention comprises an IC having a core logic area surrounded by first set of bond pads, each bond pad in the first set of bond pads disposed in a bond-pad ring and operable to provide a external signal connection point and a second set of bond pads, each bond pad in the second set of bond pads disposed in core logic area and operable to provide a external signal connection point.

Such an integrated circuit is able to be designed and manufactured smaller than conventional ICs because additional bond pads are disposed in the core logic area of the IC. As such, additional space in the bond-pad ring is not required and the overall size of the IC remains the same after additional bond pads are added because the additional bond pads may be implemented in the wasted space in the core logic area of an IC that is pad-limited in its design.

Furthermore, the presence of power and ground terminals in the core logic area may help reduce the effects of electromagnetic interference in the core logic area as caused by external sources such as high-speed data busses and the like.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A is a top view of a conventional IC having an inline bond-pad ring pattern;

FIG. 1B is a top view of a conventional IC having a staggered bond-pad ring pattern;

FIG. 2 is a top view of an IC having inner bond pads disposed in the core logic area as well as outer bond pads around the bond-pad ring according to an embodiment of the invention;

FIG. 3 is a top view of an IC also having additional bond pads disposed in the core logic area according to another embodiment of the invention;

FIG. 4 is another top view of another IC also having additional inner bond pads disposed in the core logic area according to another embodiment of the invention; and

FIG. 5 is a diagram of an electronic system having at least one of the embodiments of the ICs shown in FIGS. 2-4 coupled with a microprocessor 501.

### DETAILED DESCRIPTION

The following discussion is presented to enable a person skilled in the art to make and use the invention. The general principles described herein may be applied to embodiments and applications other than those detailed above without departing from the spirit and scope of the present invention. The present invention is not intended to be limited to the embodiments shown, but is to be accorded the widest scope consistent with the principles and features disclosed or suggested herein.

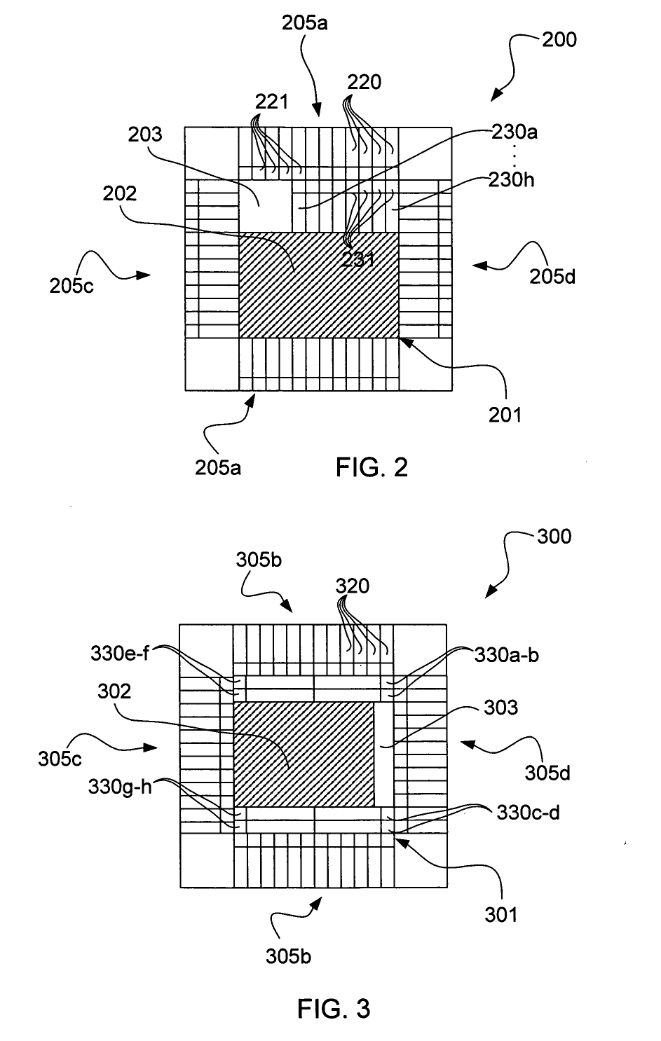

FIG. 2 is a top view of an IC 200 having inner bond pads 230a-h disposed in the core logic area 201 as well as outer bond pads 220 around the bond-pad ring 205 according to an embodiment of the invention. The IC 200 includes a core logic area 201 that is surrounded by a bond-pad ring 205. The term bond-pad ring 205 refers to the entire outer bond pad area in FIG. 2 which includes the outer bond pads 220 that form the top 205a, bottom 205b, left 205c and right 205d sides of the bond-pad ring 205. The reference to bond pads 220 refers to any of the outer bond pads in the bond-pad ring 205, however, for clarity, only a few outer bond pads are referenced in FIG. 2.

In this embodiment, the bond pads 220 of the bond-pad ring 205 are configured in an inline bond pad pattern (as described above). However, the outer bond pads 220 may be configured in any pattern including the staggered pattern also described above. Further, the outer bond pads 220 in the top side 205a of the bond-pad ring 205 are also configured such that bond site 221 of each outer bond pad 220 is closest to the core logic area 201. In contrast, the remaining three sides (bottom 205b, left 205c and right 205d) the bond sites 221 of each of the outer bond pads 220 are furthest from the core logic area 201. In other embodiments (not shown), the bond sites 221 of the outer bond pads 220 in the bond-pad ring 205 may also be farthest from the core logic area 201 in an opposite manner than what is shown in FIG. 2 or a mix and match of different directions in which the bond sites 221 of each of the outer bond pads 220 are configured.

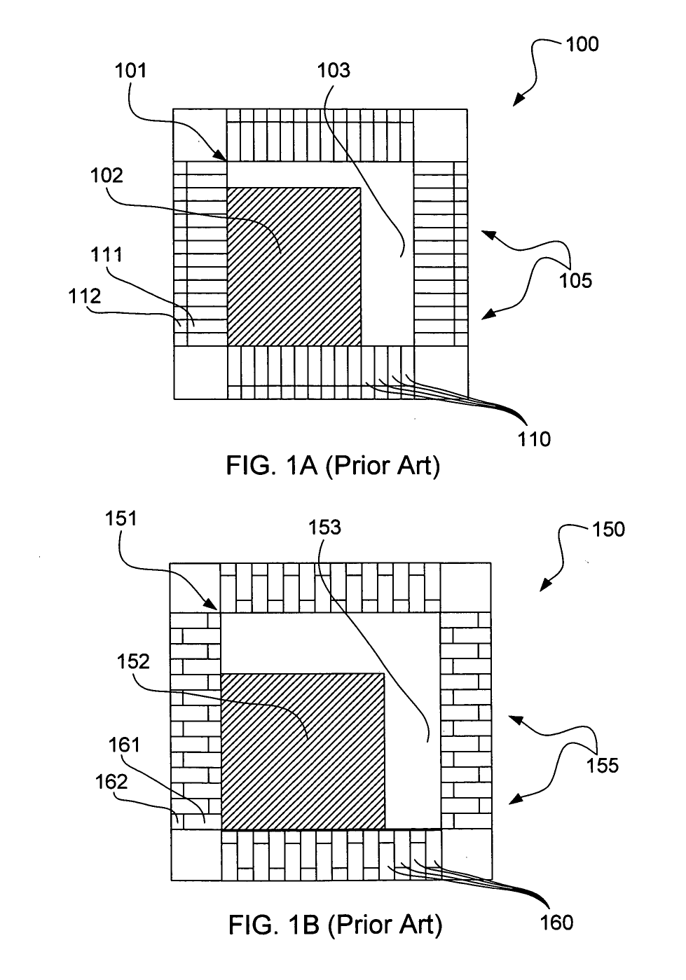

The IC 200 of FIG. 2 also includes a set of inner bond pads 230a-h that are disposed within the interior core logic area 201. That is, in additional to the outer bond pads 220 in the bond-pad ring 205, additional inner bond pads 230a-h are disposed in the core logic area 201 such that the overall number of bond pads is increased because space for bond pads is used in an area not conventionally used for pads in the past (the core logic area 201). Thus, in comparison to the ICs 100 and 150 of FIGS. 1A and 1B (each of which had 14 bond pads per side resulting in a total of 56 bond pads), the IC 200 of FIG. 2 also has 56 bond pads, however, only 12 of which are disposed per side in the bond-pad ring 205 for a total of 48 on the bond-pad ring 205 of the IC 200. The remaining 8 bond pads 230a-h are disposed in the core logic area 201. Therefore, the overall size of the IC 200 may be smaller than the examples of FIGS. 1A and 1B because only 12 bond pads comprise each side of the bond-pad ring 205.

The total area used for the core logic 202 is still smaller than the available space in the core logic area 201, but the amount of wasted space 203 is decreased. As such, additional inner bond pads 230a-h can be realized without increasing the size of the IC 200 because no additional outer bond pads 220 need to be included in the bond-pad ring 205 configuration. Thus, in an IC 200 that has extra, unused space 203 in the core logic area 201, additional inner bond pads 230a-h can be added without adding to the size of the bond-pad ring 205. One can easily increase the number of inner bond pads 230 in concert with additional core logic 202 until the wasted space 203 becomes negligible or even eliminated.

In the embodiment shown in FIG. 2, the inner bond pads 230a-h are arranged in an inline pattern and have their respective bond sites 231 configured to be closest to the bond-pad ring 205. By having the bond sites 231 closer to the outside edge of the IC 200, any bond wires (not shown) that may attach to the bond sites 231 will have a shorter length to travel to get off chip, thus minimizing the required size of the bond wire and subsequently minimizing the required size of the bond site 231 on the bond pads 230a-h.

A typical bond pad 220 or 230a-h may be designed for one of three types of signals. First, a bond pad may be designed for an I/O signal. This type of bond pad typically has additional I/O circuitry in its bond-pad logic area in order to accommodate the logical circuitry typically required for signal conditioning (buffering, voltage translations, etc.). Thus, the length of the bond pad is a function of the amount of logical circuitry in its bond-pad logic area. Consequently, all bond pads are also this length for uniformity sake around the bond-pad ring 205. Second, a bond pad may be designed to be a power terminal for supplying power to the core logic 202. Not as much logic circuitry is required for power terminals. Third, a bond pad may be designed to be a ground terminal to be connected to the core logic 202. Again, not as much logic circuitry is required for ground terminals.

Some bond pads 220 or 230a-h may not require a connection to a bond wire that traverses the bond-pad ring 205 in order to interface with external components. For example, if the bond pad 230a-h is designed to be a power terminal, the bond pad 230a-h may be connected to the substrate package (not shown) of the IC 200. This is known as downbonding as the power or ground terminal is coupled to the substrate package through the die of the IC 200 in an area between the bond-pad ring 205 and the core-logic area 201. Thus, power and ground bond pads are well suited to be disposed in the core logic area 201 because larger and longer bond wire runs may not be required.

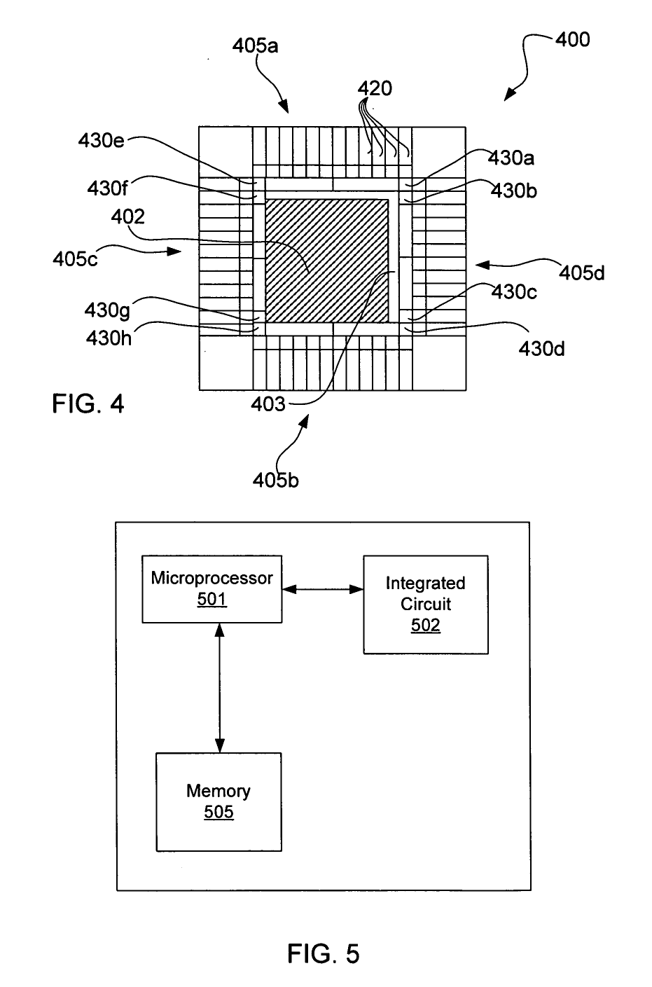

The additional bond pads 230a-h in FIG. 2 are shown in a single area of the core logic area 201 and are all arranged in an inline pattern. However, the additional bond pads 230a-h need not be arranged so tightly and uniformly. For example, the bond pads 230a-h may be arranged in a staggered pattern. Other examples are described with respect to FIGS. 3 and 4 below.

FIG. 3 is a top view of an IC 300 also having additional bond pads 330a-h disposed in the core logic area 301 according to another embodiment of the invention. These additional bond pads 330a-h are arranged differently, however, from the previous embodiment of FIG. 2.

Again, the IC 300 includes a core logic area 301 that is surrounded by a bond-pad ring 305. The outer bond pads 320 of the bond-pad ring 305 are configured in an inline bond pad pattern in FIG. 3, however, may be configured in any pattern including the staggered pattern described above. Further, the outer bond pads 320 are also configured such that each bond site 321 of each outer bond pad 320 is closest to the core logic area 301. Again, although not shown, the bond sites 321 of the outer bond pads 320 in the bond-pad ring 305 may also be farthest from the core logic area 301 in an opposite manner than what is shown in FIG. 3.

The IC 300 of FIG. 3 also includes a set of inner bond pads 330a-h that are disposed within the core logic area 301. That is, in additional to the outer bond pads 320 in the bond-pad ring 305, additional inner bond pads 330a-h are disposed in the core logic area 301 such that the overall number of bond pads is increased. Thus, in comparison to the ICs 100 and 150 of FIGS. 1A and 1B (each of which had 14 bond pads per side resulting in a total of 56 bond pads), the IC 300 of FIG. 3 also has 56 bond pads, however, only 12 of which are disposed per side on the bond-pad ring 305 for a total of 48 on the outer edge of the IC300. The remaining 8 inner bond pads 330a-h are disposed in the core logic area 301. Therefore, the overall size of the IC 300 is smaller than the examples of FIGS. 1A and 1B because only 12 bond pads comprise each side of the bond-pad ring 305.

As was the case with the embodiment of FIG. 2, the total area used for the core logic 302 is still smaller than the available space in the core logic area 301, but the amount of wasted space 303 is again decreased. As such, additional inner bond pads 330 can be realized without increasing the size of the IC 300 because no additional outer bond pads 320 need to be included in the bond-pad ring 305. Thus, in an IC 300 that has extra, unused space 303 in the core logic area 301, additional inner bond pads 330a-h can be added without adding size to the bond-pad ring 305.

In the embodiment shown in FIG. 3, the additional inner bond pads 330a-h are arranged in a semi staggered pattern and have their respective bond sites 332 configured to be closest to the bond-pad ring 305 albeit not all arranged inline as was the case in the embodiment shown in FIG. 2. Essentially, the additional bond pads 330a-h of FIG. 3 are spread apart such that of the eight additional bond pads 330a-h, sets of two inner bond pads (330a-b, 330c-d, 330e-f, and 330g-h) are configured in each corner of the core logic area 301. Further, each inner bond pad 330e-h on the left side has its respective bond site closest to the bond sites of the outer bond pads 320 on the left side 305c of the bond-pad ring 305. Likewise, each inner bond pad 330a-d on the right side has its respective bond site closest to the bond sites of the outer bond pads 320 on the right side 305d of the bond-pad ring 305. Each inner bond pad has a bond-pad logic area that extends inward toward the center of the core logic area 301. Thus, the bond sites of each inner bond pad 330a-h still remain closest to the bond-pad ring, but the manner in which each additional bond pad is arranged differs in each corner of the core logic area 301 as shown.

FIG. 4 is another top view of another IC 400 also having additional inner bond pads 430a-h disposed in the core logic area 401 according to another embodiment of the invention. These additional inner bond pads 430a-h are again arranged differently from the previous embodiments of FIGS. 2 and 3.

Again, the IC 400 includes a core logic area 401 that is surrounded by a bond-pad ring 405. The outer bond pads 420 of the bond-pad ring 405 are configured in an inline bond-pad pattern in FIG. 4, however, they may be configured in any pattern including the staggered pattern described above. Further, the outer bond pads 420 are also configured such that each bond site 421 of each outer bond pad 420 is closest to the core logic area 401. Again, although not shown, the bond sites 421 of the outer bond pads 420 in the bond-pad ring 405 may also be farthest from the core logic area 401 in an opposite manner than what is shown in FIG. 4.

The IC 400 of FIG. 4 also includes a set of inner bond pads 430a-h that are within the interior core logic area 401. That is, in additional to the outer bond pads 420 in the bond-pad ring 405, additional inner bond pads 430a-h are disposed in the core logic area 401 such that the overall number of bond pads is increased. Thus, in comparison to the ICs 100 and 150 of FIGS. 1A and 1B (each of which had 14 bond pads per side resulting in a total of 56 bond pads), the IC 400 of FIG. 4 also has 56 bond pads, however, only 12 of which are disposed per side on the bond-pad ring 405 for a total of 48 on the outer edge of the IC 400. The remaining 8 bond pads 430 are disposed in the core logic area 401. Therefore, the overall size of the IC 400 is smaller than the examples of FIGS. 1A and 1B because only 12 bond pads comprise each side of the bond-pad ring 405.

As was the case with the embodiment of FIGS. 2 and 3, the total area used for the core logic 402 is still smaller than the available space in the core logic area 401, but the amount of wasted space 403 is again decreased. As such, additional inner bond pads 430a-h can be realized without increasing the size of the IC 400 because no additional outer bond pads 420 need to be included in the bond-pad ring 405. Thus, in an IC 400 that has extra, unused space 403 in the core logic area 401, additional inner bond pads 430a-h can be added without adding to the bond-pad ring 405.

In the embodiment shown in FIG. 4, the additional inner bond pads 430a-h are arranged in a multi-staggered pattern and have their respective bond sites configured to be closest to the bond-pad ring 405 albeit not all arranged inline as was the case in the embodiment shown in FIG. 2. Essentially, the additional inner bond pads 430a-h of FIG. 4 are spread apart such that of the eight additional bond inner pads 430a-h, individual bond pads are configured in each corner with the respective bond pad logic area extending in perpendicular directions from each corner of the core logic area 401 into the interior of the IC 300. That is, the bond sites of each additional bond pad 330a-h still remain closest to the bond-pad ring 405, but the manner in which each additional bond pad is arranged differs in each corner as shown.

Thus, in the top right corner of the core logic area, a first inner bond pad 430a has a bond site closest to the bond sites of the outer bond pads 420 in the top array 405a of the bond-pad ring 405 and has a bond pad logic area that extends to the left of its bond site. In the same top right corner, a second inner bond pad 430b has a bond site closest to the bond sites of the outer bond pads 420 in the right array 405d of the bond-pad ring 405 and has a bond pad logic area that extends down from its bond site. Similarly, in the top left corner of the core logic area, a first inner bond pad 430e has a bond site closest to the bond sites of the outer bond pads 420 in the top array 405a of the bond-pad ring 405 and has a bond pad logic area that extends to the right of its bond site. In the same top left corner, a second inner bond pad 430f has a bond site closest to the bond sites of the outer bond pads 420 in the left array 405c of the bond-pad ring 405 and has a bond pad logic area that extends down from its bond site. The other two corners, the bottom left and the bottom right, of the core logic area also have two inner bond pads 430c-d and 430g-h configured in a similar, albeit opposite, manner as described with respect to the top left and top right corners.

Another advantage of disposing inner bond pads 430a-h in the core logic area 401 is the reduction of stray electromagnetic waves that may lead to electromagnetic interference (EMI) problems with the circuitry of the IC 400. When an IC 400 is part of a larger electronic system, various other components, such as powerful microprocessors or high-speed data busses of the system, may generate and propagate signals that may cause EMI. Power and ground terminals on the IC 400 help reduce the effects of EMI by essentially generating a different frequency of interference. Since the frequency of power and ground signals are not nearly as fast as EMI signals from high-speed data busses and the like, the low-frequency EMI generated by the power and ground bond pads can disrupt the EMI from other higher-frequency sources. The result is that the logical circuitry near the power and ground terminals, i.e., the core logic area 401, is able to operate in an environment cleaner than an environment not near power and ground bond pads.

Thus, as more power and ground bond pads are disposed inside the core logic area 401, for example, as inner bond pads 430a-h, the more the effects of EMI generated off-chip can be reduced. As such, if one were to arrange the inner bond pads 430a-h to be evenly spaced at the outside edges of the core logic area 401, a reduction in EMI at the core logic area 401 can be achieved.

FIG. 5 is a diagram of an electronic system having at least one of the embodiments of the ICs shown in FIGS. 2-4 coupled with a microprocessor 501. Integrated circuits, such as IC 502, can be designed to accomplish a number of tasks for a microprocessor 501 in any electronic system. For example, the IC 502 may be designed to process digital signals received from a memory chip 505 in order to convert data stored in the memory 505 from one format to another. In any case, in the system of FIG. 5, the IC 502 is coupled with and in communication with the microprocessor 501 and is configured such that the microprocessor 501 may control or otherwise take advantage of the functionality of the IC 502.

1. An integrated circuit, comprising:
a core logic area surrounded by a bond-pad ring;
a first set of bond pads, each bond pad in the first set of bond pads disposed in bond-pad ring and operable to provide a external signal connection point; and
a second set of bond pads, each bond pad in the second set of bond pads disposed in core logic area and operable to provide a external signal connection point.

2. The integrated circuit of claim 1 wherein the core logic area is arranged in a rectangle having four sides and the bond-pad ring surrounding the core logic area comprises four subsets of bond pads respectively adjacent to the four sides of the rectangular core logic area.

3. The integrated circuit of claim 2 wherein the bond pads in the four sub-sets of bond pads are arranged in an inline bond ring pattern.

4. The integrated circuit of claim 2 wherein the bond pads in the four sub-sets of bond pads are arranged in staggered bond ring pattern.

5. The integrated circuit of claim 1 wherein the bond pads in the second set of bond pads comprise at least one power bond pad.

6. The integrated circuit of claim 1 wherein the bond pads in the second set of bond pads comprise at least one ground bond pad.

7. The integrated circuit of claim 1 wherein the bond pads in the second set of bond pads are arranged in an inline pattern, each having a respective bond site disposed closest to the first set of bond pads.

8. The integrated circuit of claim 1 wherein the bond pads in the second set of bond pads are configured to reduce electromagnetic interference in the core logic area.

9. The integrated circuit of claim 8 wherein the bond pads in the second set of bond pads are configured in a semi-staggered configuration.

10. The integrated circuit of claim 8 wherein the bond pads in the second set of bond pads are configured in a multi-staggered configuration.

11. The integrated circuit of claim 1 coupled to a microprocessor and operable to be controlled by the microprocessor.

12-20. (canceled)
